(19) United States
(12) Patent Application Publication
(10) Pub. No.: US 2026/0040596 A1
(43) Pub. Date: Feb. 5, 2026

(54) INSULATED GATE BIPOLAR TRANSISTOR AND MANUFACTURING METHOD THEREOF, AND ELECTRONIC DEVICE

(71) Applicant: Glenfly Tech Co., Ltd., Shanghai (CN)

(72) Inventors: Tao ZHANG, Shanghai (CN); Na LI, Shanghai (CN)

(21) Appl. No.: 19/213,516

(22) Filed: May 20, 2025

(30) Foreign Application Priority Data
Jul. 31, 2024 (CN) 202411046579.5

(51) Int. Cl. H10D 12/00; H10D 12/01; H10D 62/10; H10D 64/27

(52) U.S. Cl. CPC H10D 12/481; H10D 12/038; H10D 62/105; H10D 62/124; H10D 64/514; H10D 64/518

(57) ABSTRACT

The present disclosure describes an insulated gate bipolar transistor and a manufacturing method thereof, and an electronic device. The insulated gate bipolar transistor comprises: a substrate of a first conductivity type; and a plurality of gate structures arranged at intervals in the substrate, each gate structure comprising a gate oxide layer, a first semiconductor doping layer, and a second semiconductor doping layer, the first semiconductor doping layer being provided on the second semiconductor doping layer, the gate oxide layer being provided on sidewalls of the first semiconductor doping layer, and a bottom portion and sidewalls of the second semiconductor doping layer, the first semiconductor doping layer having the first conductivity type, and the second semiconductor doping layer having a second conductivity type opposite to the first conductivity type.

### CROSS-REFERENCE TO RELATED APPLICATION

The application claims priority to Chinese Patent Application No. 202411046579.5, filed with the China National Intellectual Property Administration on Jul. 31, 2024, and entitled “Insulated Gate Bipolar Transistor and Manufacturing Method thereof, and Electronic Device”, which is incorporated herein by reference in its entirety.

### TECHNICAL FIELD

The present disclosure relates to the field of semiconductor technology, particularly to an insulated gate bipolar transistor and a manufacturing method thereof, and an electronic device.

### BACKGROUND

With the development of semiconductor technology, Insulated Gate Bipolar Transistor (IGBT) is widely used due to advantages of high input impedance, low forward voltage drop, and fast switching speed.

However, when the IGBT is used in a high-voltage and high-current working scenario, the IGBT needs to operate in a high-voltage environment for a long time, which places a high requirement on voltage withstand of the IGBT. The conventional IGBT is prone to breakdown.

### SUMMARY

In view of this, it is necessary to provide an insulated gate bipolar transistor and a manufacturing method thereof, and an electronic device in order to address the above technical problem that the IGBT is prone to breakdown.

In the first aspect of the present disclosure, an insulated gate bipolar transistor is provided, which may include: a substrate of a first conductivity type; and a plurality of gate structures arranged at intervals in the substrate, each gate structure including a gate oxide layer, a first semiconductor doping layer, and a second semiconductor doping layer, the first semiconductor doping layer being provided on the second semiconductor doping layer, the gate oxide layer being provided on sidewalls of the first semiconductor doping layer, and a bottom portion and sidewalls of the second semiconductor doping layer, the first semiconductor doping layer having the first conductivity type, and the second semiconductor doping layer having a second conductivity type opposite to the first conductivity type.

In an embodiment, the insulated gate bipolar transistor may further include: a body region of the second conductivity type located on the substrate of the first conductivity type and provided around each first semiconductor doping layer. A depth of the body region is less than a depth of each first semiconductor doping layer in a direction perpendicular to the substrate.

In an embodiment, the insulated gate bipolar transistor may further include: an active region of the first conductivity type located on the body region and provided around the gate structures.

In an embodiment, the first conductivity type is N-type and the second conductivity type is P-type.

In an embodiment, the insulated gate bipolar transistor may further include: a collector layer of the second conductivity type located on a surface of the substrate away from the gate structures.

In an embodiment, an upper surface of the active region is aligned with an upper surface of each gate structure.

In the second aspect of the present disclosure, a method for manufacturing an insulated gate bipolar transistor is provided, which may include: providing a substrate of a first conductivity type; forming a plurality of trench structures arranged at intervals in the substrate; forming a gate oxide layer at a bottom portion and sidewalls of each trench structure; forming a second semiconductor doping layer on a side of the gate oxide layer away from the trench structure, a height of a top portion of the second semiconductor doping layer being less than a height of a top portion of the trench structure, the second semiconductor doping layer having a second conductivity type opposite to the first conductivity type; and forming a first semiconductor doping layer of the first conductivity type on the second semiconductor doping layer, wherein the gate oxide layer, the first semiconductor doping layer, and the second semiconductor doping layer form a gate structure.

In an embodiment, the method may further include: injecting ions of the second conductivity type into the substrate to form a body region, wherein a depth of the body region is less than a depth of the first semiconductor doping layer in a direction perpendicular to the substrate.

In an embodiment, the method may further include: injecting ions of the first conductivity type into the substrate above the body region to form an active region.

In an embodiment, the method may further include: forming a collector layer of the second conductivity type on a lower surface of the substrate.

In an embodiment, the step of forming the collector layer of the second conductivity type on a lower surface of the substrate may include: thinning a side of the substrate away from the gate structures, and injecting P-type ions to form the collector layer.

In an embodiment, the step of forming the collector layer of the second conductivity type on a lower surface of the substrate may include: depositing a metal layer on a side of the collector layer away from the substrate, where the collector layer is connected to an external circuit through the metal layer.

In the third aspect of the present disclosure, an electronic device is provided, which may include the insulated gate bipolar transistor in any of the above-mentioned embodiments.

In the insulated gate bipolar transistor and the manufacturing method thereof, and the electric device, the insulated gate bipolar transistor includes a substrate of a first conductivity type and a plurality of gate structures, the plurality of gate structures are provided at intervals in the substrate, each gate structure includes a gate oxide layer, a first semiconductor doping layer of the first conductivity type, and a second semiconductor doping layer of the second conductivity type, the first semiconductor doping layer is provided on the second semiconductor doping layer, and the gate oxide layer is provided on the sidewalls of the first semiconductor doping layer, and the bottom portion and sidewalls of the second semiconductor doping layer. During the use of the IGBT in the present disclosure, the second semiconductor doping layer is combined with the first semiconductor doping layer to form a reverse PN junction, and the reverse PN junction can withstand the reverse voltage after the bottom portion of the gate oxide layer broken down, thereby avoiding the occurrence of IGBT failure due to the short circuit between the first semiconductor doping layer and the substrate. Accordingly, the reverse voltage withstand capability of the IGBT is improved and the voltage withstand level of the IGBT is improved.

### BRIEF DESCRIPTION OF THE DRAWINGS

In order to describe the technical solution in the embodiments of the present disclosure or the related technologies more clearly, the accompanying drawings required for describing the embodiments of the present disclosure or the related technologies are briefly introduced. Obviously, the accompanying drawings in the following description show merely some embodiments of the present disclosure, and those skilled in the art may still obtain other related drawings according to these accompanying drawings without any creative efforts.

FIG. 1 is a cross-sectional view of an insulated gate bipolar transistor according to an embodiment.

FIG. 2 is a cross-sectional view of an insulated gate bipolar transistor according to another embodiment.

FIG. 3 is a flow chart showing a method for manufacturing an insulated gate bipolar transistor according to an embodiment.

FIG. 4 is a cross-sectional view of a structure obtained by forming a gate oxide layer at a bottom portion and a sidewall of a trench structure in step S130 according to an embodiment.

FIG. 5 is a cross-sectional view of a structure obtained by step S140 in one embodiment: forming a second semiconductor doping layer on a side of the gate oxide layer away from the trench structure;

FIG. 6 is a curve graph showing a relationship between a leakage current and a breakdown voltage of an IGBT.

FIG. 7 shows an output characteristic curve of an IGBT.

FIG. 8 shows a transfer characteristic curve of an IGBT.

### REFERENCE SIGNS

100, substrate; 200, gate structure; 210, gate oxide layer; 220, first semiconductor doping layer; 230, second semiconductor doping layer; 300, body region; 400, active region; 500, collector layer.

### DETAILED DESCRIPTION OF THE EMBODIMENTS

In order to facilitate understanding of the present disclosure, the present disclosure will be described more comprehensively below with reference to the relevant accompanying drawings. Embodiments of the present disclosure are shown in the accompanying drawings. However, the present disclosure may be implemented in many different forms and is not limited to the embodiments described herein. Rather, the purpose of providing these embodiments is to make the present disclosure more thorough and complete.

Unless defined otherwise, all technical and scientific terms used herein have the same meaning as commonly understood by one of ordinary skill in the art to which the present disclosure belongs. The terms used herein in the specification of the present disclosure are only for the purpose of describing specific embodiments and are not intended to limit the present disclosure.

It should be appreciated that when a component or a layer is referred to as being “on”, “adjacent to”, “connected to”, or “coupled to” another component or layer, it may be directly on, adjacent to, connected to or coupled to another component or layer, or through an intermediate component or layer. Rather, when a component is referred to as being “directly on”, “directly adjacent to”, “directly connected to”, or “directly coupled to” another component or layer, there is no intermediate component or layer. It should be appreciated that although the terms “first, second, third, etc.,” may be used to describe layers or conductivity types, these layers or conductivity types should not be limited by these terms. These terms are used only to distinguish one layer or conductivity type from another. Therefore, without departing from the teaching of the present disclosure, the first layer or conductivity type discussed below may be represented as the second layer or conductivity type, for example, the first conductivity type may be referred to as the second conductivity type, and similarly, the second conductivity type may be referred to as the first conductivity type. Alternatively, the first conductivity type and the second conductivity type are different conductivity types, for example, the first conductivity type may be P-type while the second conductivity type may be N-type, or the first conductivity type may be N-type while the second conductivity type may be P-type.

Spatial relationship terms such as “beneath”, “below”, “under”, “lower”, “upper”, “above”, etc., may be used herein to describe a relationship of one component or feature and other components or features shown in the figures. It will be appreciated that the spatial relationship terms may further include different orientations of a device in use and operation in addition to the orientations depicted in the figures. For example, if the device in the figures is turned over, a component feature described as being “below” or “beneath” or “under” other component may be oriented “above” the other components or features. Thus, the exemplary terms “below”, “under” may include both up and down orientations. Furthermore, the device may have other orientations (e.g., rotated 90 degrees or at other orientations), and the spatial descriptors used herein interpreted accordingly.

As used herein, the singular forms “a”, “an” and “the/said” may also include the plural forms, unless the context clearly indicates otherwise. It should also be appreciated that the terms “include/comprise” or “have” and the like specify the presence of stated features, wholes, steps, operations, components, portions or combinations thereof, but do not exclude the possibility of the presence or addition of one or more other features, wholes, steps, operations, components, portions or combinations thereof. Meanwhile, in the specification, the term “and/or” includes any and all combinations of the listed relevant items.

Embodiments of the present disclosure are described herein with reference to cross-sectional diagrams of schematic illustrations of exemplary embodiments (and intermediate structures) of the present disclosure so that changes in shapes of the illustrations as a result, for example, of manufacturing techniques and/or tolerances can be predicted. Accordingly, embodiments of the present disclosure should not be limited to the particular shapes of regions illustrated herein but are to include deviations in shapes that result, for example, from manufacturing techniques. For example, an implanted region illustrated as a rectangle may typically have rounded or curved features and/or an injection concentration gradient at an edge thereof, rather than a binary change from an injection region to a non-injection region. Similarly, a buried region formed by injection may result in some injection in a region between the buried region and a surface through which the injection is performed. Thus, the regions illustrated in the figures are schematic in nature, shapes of the regions are not intended to illustrate the actual shapes of the regions on the device and are not intended to limit the scope of the present disclosure.

IGBTs are widely used in high-voltage and high-current working scenarios due to the advantages of high input impedance, low forward voltage drop, and fast switching speed. The IGBT needs to have a high voltage withstand level in order to operate in a high-voltage environment for a long time.

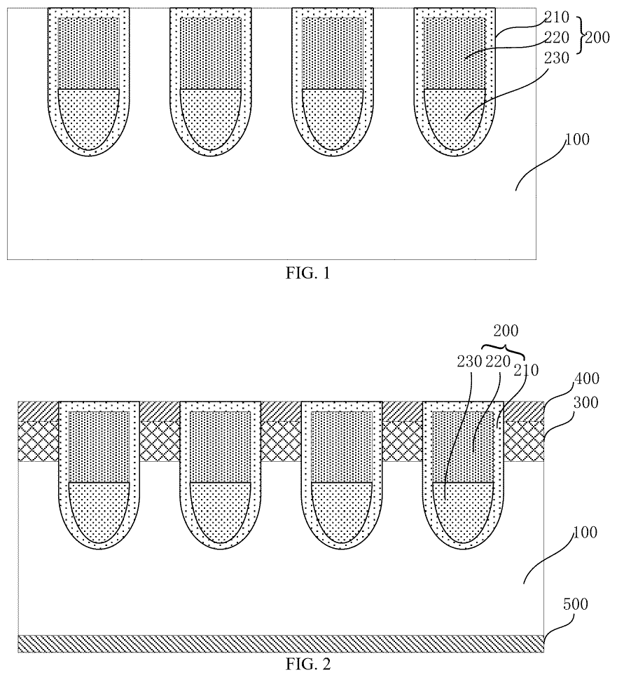

Based on this, the present disclosure proposes an insulated gate bipolar transistor with a high voltage withstand. As shown in FIG. 1, the insulated gate bipolar transistor includes a substrate 100 of a first conductivity type and a plurality of gate structures 200. The plurality of gate structures 200 are provided at intervals in the substrate 100. Each gate structure 200 includes a gate oxide layer 210, a first semiconductor doping layer 220, and a second semiconductor doping layer 230. The first semiconductor doping layer 220 is provided on the second semiconductor doping layer 230. The gate oxide layer 210 is provided on sidewalls of the first semiconductor doping layer 220, and a bottom portion and sidewalls of the second semiconductor doping layer 230. The gate oxide layer 210 surrounds the first semiconductor doping layer 220 and the second semiconductor doping layer 230. The first semiconductor doping layer 220 is of the first conductivity type, and the second semiconductor doping layer 230 is of a second conductivity type. The first conductivity type is opposite to the second conductivity type. Exemplarily, the first conductivity type is N-type, and the second conductivity type is P-type. The substrate 100 may be an N-type germanium substrate, an N-type silicon substrate, or an N-type silicon carbide substrate, etc. The first semiconductor doping layer 220 may be N-type polysilicon, and the second semiconductor doping layer 230 may be P-type polysilicon.

During the manufacturing process of the IGBT, due to the influence of the process, materials, environment, etc., certain defects may inevitably exist in the gate oxide layer 210. When a high voltage is applied to the gate structure 200, defects in the gate oxide layer 210 may form electron traps. As the voltage on both sides of the gate oxide layer 210 increases, electrons in the gate oxide layer 210 move to form a current path. When the current is discharged through the current path formed by the defects in the gate oxide layer 210, the gate oxide layer 210 may be broken down and the gate structure 200 may be destroyed. A thin gate oxide layer is more prone to breakdown than a thick gate oxide layer.

When the IGBT is subjected to a reverse high voltage, the bottom portion of the gate oxide layer 210 is a high electric field region, which is a weak point for electrical breakdown. For the IGBT in the embodiment, the first semiconductor doping layer 220 in the gate structure 200 can serve as a gate electrode. When the IGBT is subjected to the reverse high voltage and the bottom portion of the gate oxide layer 210 is broken down, the second semiconductor doping layer 230 located on an upper side of the bottom portion of the gate oxide layer 210 is combined with the first semiconductor doping layer 220 to form a reverse PN junction, which can withstand the high voltage, and avoid a short circuit between the first semiconductor doping layer 220 and the substrate 100.

In the present embodiment, the insulated gate bipolar transistor includes a substrate 100 of a first conductivity type and a plurality of gate structures 200. The plurality of gate structures 200 are provided at intervals in the substrate 100. Each gate structure 200 includes a gate oxide layer 210, a first semiconductor doping layer 220 of the first conductivity type, and a second semiconductor doping layer 230 of the second conductivity type. The first semiconductor doping layer 220 is provided on the second semiconductor doping layer 230, and the gate oxide layer 210 is provided on the sidewalls of the first semiconductor doping layer 220, and the bottom portion and sidewalls of the second semiconductor doping layer 230. During the use of the IGBT in the embodiment, the second semiconductor doping layer 230 is combined with the first semiconductor doping layer 220 to form a reverse PN junction, and the reverse PN junction can withstand the reverse voltage after the bottom portion of the gate oxide layer 210 is broken down, thereby avoiding the IGBT failure due to the short circuit between the first semiconductor doping layer 220 and the substrate 100. Accordingly, the reverse voltage withstand capability of the IGBT is improved and the voltage withstand level of the IGBT is improved.

In an embodiment, as shown in FIG. 2, the insulated gate bipolar transistor may further include a body region 300 of the second conductivity type. The body region 300 is located on the substrate 100 of the first conductivity type and is provided around the first semiconductor doping layer 220.

In a direction perpendicular to the substrate 100, a depth of the body region 300 is less than a depth of the first semiconductor doping layer 220. A height of an upper surface of the first semiconductor doping layer 220 is taken as a reference line, the depth of the first semiconductor doping layer 220 is equal to a distance from the bottom portion to the upper surface of the first semiconductor doping layer 220, and the depth of the body region 300 is equal to a distance from a bottom portion of the body region 300 to the upper surface of the first semiconductor doping layer 220. When the positive voltage applied to the gate structure 200 gradually increases and exceeds a threshold voltage of the IGBT, a partial body region 300 adjacent to the first semiconductor doping layer 220 forms an inversion layer, and the IGBT is turned on. Since the second semiconductor doping layer 230 is located under the first semiconductor doping layer 220 and is away from the body region 300, after a voltage is applied to the second semiconductor doping layer 230, the inversion layer formed in the body region 300 is not affected.

In an embodiment, referring to FIG. 2, the insulated gate bipolar transistor may further include an active region 400 of the first conductivity type. The active region 400 is located on the body region 300 and is provided around the gate structure 200. An upper surface of the active region 400 is aligned with an upper surface of the gate structure 200. A metal layer is disposed on the upper surface of the active region 400 to form an emitter of the IGBT.

In an embodiment, referring to FIG. 2, the insulated gate bipolar transistor may further include a collector layer 500 of the second conductivity type, which is located on a surface of the substrate 100 away from the gate structures 200.

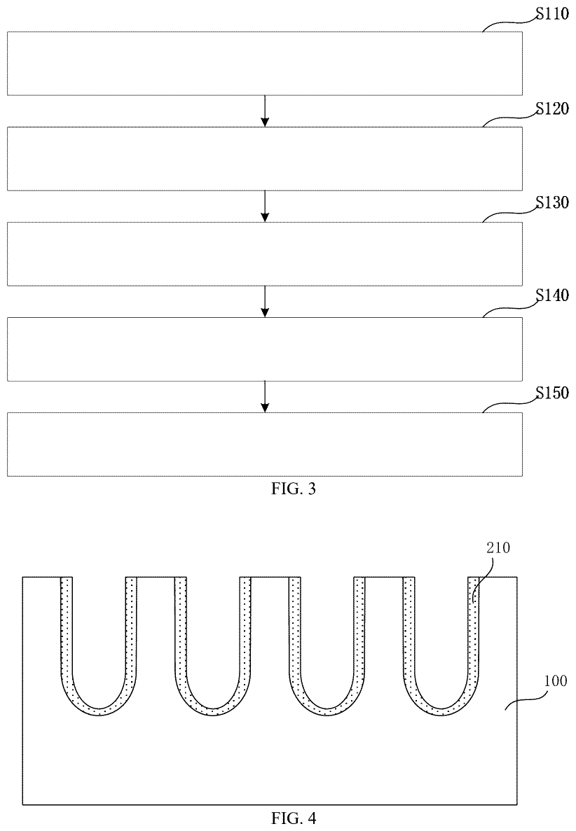

In an embodiment of the present disclosure, as shown in FIG. 3, a method for manufacturing an insulated gate bipolar transistor is further provided, which includes the following steps S110 to S150.

S110: a substrate of a first conductivity type is provided.

The material of the substrate 100 may be germanium, silicon, silicon carbide, etc. The substrate 100 of the first conductivity type may be formed by doping an appropriate amount of ions of the first conductivity type into the material such as germanium, silicon, or silicon carbide. Exemplarily, the first conductivity type is N-type, and an N-type substrate can be formed by doping an appropriate amount of N-type ions (such as phosphorus, arsenic, etc.) into the material such as germanium, silicon, or silicon carbide, etc.

S120: a plurality of trench structures arranged at intervals are formed in the substrate.

A plurality of trench structures arranged at intervals may be formed in the substrate 100 by lithography, etching or other processes.

S130: a gate oxide layer is formed at a bottom portion and sidewalls of each trench structure.

As shown in FIG. 4, a gate oxide layer 210 may be formed on the bottom portion and sidewalls of each trench structure through a deposition process. As an example, the gate oxide layer 210 may be made of a silicon dioxide material, a silicon oxycarbide material, or the like.

S140: a second semiconductor doping layer is formed on a side of the gate oxide layer away from the trench structure, where the second semiconductor doping layer is of a second conductivity type, and the first conductivity type is opposite to the second conductivity type.

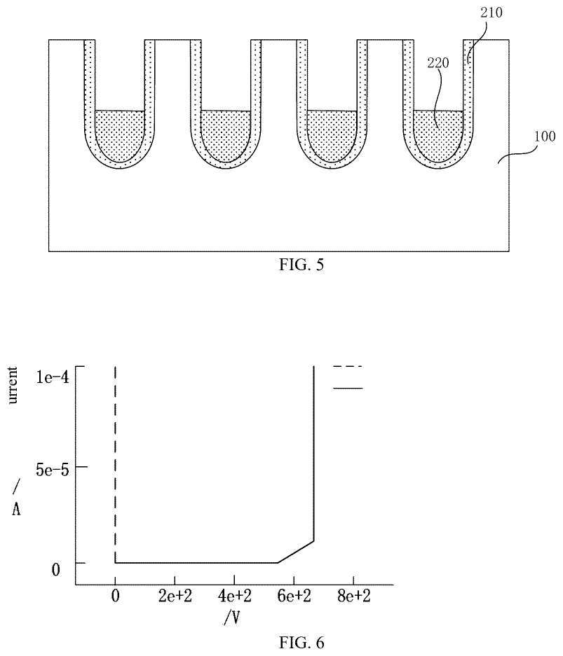

As shown in FIG. 5, a height of a top portion of the second semiconductor doping layer 230 is less than a height of a top portion of the trench structure. Exemplarily, the second conductivity type may be P-type. The P-type polysilicon material may be deposited on a side of the gate oxide layer 210 away from the trench structure through the deposition process to form the second semiconductor doping layer 230. It should be appreciated that a hole is formed on the side of the gate oxide layer 210 away from the trench structure, and the second semiconductor doping layer 230 is located at a bottom portion of the hole and does not fully fill the hole.

S150: a first semiconductor doping layer is formed on the second semiconductor doping layer, where the first semiconductor doping layer is of the first conductivity type.

For example, as shown in FIG. 1, the N-type polysilicon material may be deposited on the second semiconductor doping layer 230 through the deposition process to form the first semiconductor doping layer 220. The gate oxide layer 210, the first semiconductor doping layer 220, and the second semiconductor doping layer 230 form the gate structure 200. Optionally, after the first semiconductor doping layer 220 is formed, an oxide layer may be formed on a top portion of the first semiconductor doping layer 220 through a thermal oxidation process, and the oxide layer and the gate oxide layer 210 together enclose the first semiconductor doping layer 220 and the second semiconductor doping layer 230.

In an embodiment of the present disclosure, the substrate 100 of the first conductive type is provided, a plurality of trench structures arranged at intervals are formed in the substrate 100, the gate oxide layer 210 is formed at the bottom portion and sidewalls of each trench structure, the second semiconductor doping layer 230 is formed on a side of the gate oxide layer 210 away from the trench structure, the first semiconductor doping layer 220 is formed on the second semiconductor doping layer 230, and the gate oxide layer 210, the first semiconductor doping layer 220, and the second semiconductor doping layer 230 form the gate structure 200. The first semiconductor doping layer 220 is of the first conductivity type, the second semiconductor doping layer 230 is of the second conductivity type, and the first conductivity type is opposite to the second conductivity type. During the use of the IGBT, the second semiconductor doping layer 230 is combined with the first semiconductor doping layer 220 to form a reverse PN junction, and the reverse PN junction can withstand the reverse voltage after the bottom portion of the gate oxide layer 210 is broken down, thereby avoiding the occurrence of IGBT failure due to the short circuit between the first semiconductor doping layer 220 and the substrate 100. Accordingly, the reverse voltage withstand capability of the IGBT is improved, and the voltage withstand level of the IGBT is improved.

It should be appreciated that, although the steps in the flow chart of FIG. 3 are displayed sequentially as indicated by the arrows, these steps are not definitely executed sequentially in the order indicated by the arrows. Unless otherwise specified herein, there is no strict order limitation for the execution of these steps, and these steps may be executed in other orders. Moreover, at least part of the steps in FIG. 3 may include multiple steps or multiple stages. These steps or stages are not definitely executed at the same moment, but can be executed at different moments. These steps or stages are not definitely executed sequentially, but may be executed in turns or alternately with other steps or at least part of the steps or stages in other steps.

In an embodiment, the method for manufacturing the insulated gate bipolar transistor may further include step S160: ions of the second conductivity type are injected into the substrate to form a body region.

Referring to FIG. 2, in the direction perpendicular to the substrate 100, the depth of the body region 300 is less than the depth of the first semiconductor doping layer 220. As an example, P-type ions may be injected into the substrate 100 to form a P-type body region 300 in the substrate 100. The body region 300 is provided around the gate structure 200. For the IGBT formed in the embodiment, after the positive voltage applied to the gate structure 200 gradually increases and exceeds the threshold voltage of the IGBT, a partial body region 300 adjacent to the first semiconductor doping layer 220 forms an inversion layer, and the IGBT is turned on. Since the second semiconductor doping layer 230 is located under the first semiconductor doping layer 220 and is away from the body region 300, after a voltage is applied to the second semiconductor doping layer 230, the inversion layer formed in the body region 300 may not be affected.

In an embodiment, the method for manufacturing the insulated gate bipolar transistor may further include step S170: ions of the first conductivity type are injected into the substrate above the body region to form an active region.

Referring to FIG. 2, as an example, N-type ions may be injected to the substrate 100 located above the body region 300 to form an active region 400. Afterward, a metal layer may be deposited on the active region 400 to form an emitter.

In an embodiment, the method for manufacturing the insulated gate bipolar transistor may further include step S180: a collector layer of the second conductivity type is formed on a lower surface of the substrate.

Referring to FIG. 2, specifically, a side of the substrate 100 away from the gate structure 200 can be thinned, and then P-type ions are injected to form a collector layer 500. Optionally, a metal layer can be deposited on a side of the collector layer 500 away from the substrate 100, and the collector layer 500 can be connected to an external circuit through the metal layer.

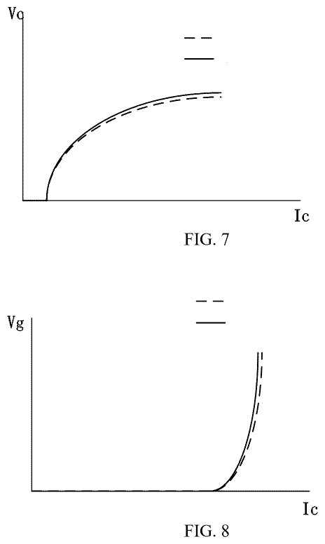

In order to better illustrate the voltage withstand of the IGBT in the present disclosure, electrical performance tests are performed on a conventional IGBT and the IGBT in the present disclosure, and the obtained results are shown in FIGS. 6 to 8. FIG. 6 is a curve diagram showing a relationship between a leakage current and a breakdown voltage. FIG. 7 is an output characteristic curve diagram, i.e., a curve showing that when the gate voltage is constant, a collector layer current Ic changes with a collector layer voltage Vc. FIG. 8 is a transfer characteristic curve diagram, i.e., a curve showing that when the collector layer voltage is constant, the collector layer current Ic changes with the gate voltage Vg. It can be seen from FIG. 6 that the conventional IGBT can only withstand a voltage of 0.8V after the bottom portion of the gate oxide layer is broken down by a high electric field, while the IGBT in the present disclosure can still withstand a voltage of 656V after the bottom portion of the gate oxide layer is broken down by a high electric field. In addition, it can be seen from FIGS. 7 and 8 that the output characteristic curve and transfer characteristic curve of the IGBT in the present disclosure almost overlap with the output characteristic curve and transfer characteristic curve of the conventional IGBT respectively. Therefore, the second semiconductor doping layer 230 provided under the first semiconductor doping layer 220 does not have a negative impact on the electrical performance of the IGBT. Accordingly, the voltage withstand level of the IGBT provided in the present application is significantly improved, while other electrical properties are not deteriorated.

In an embodiment of the present disclosure, an electronic device is further provided, which includes the insulated gate bipolar transistor provided in any of the above embodiments. Since the gate structure 200 in the insulated gate bipolar transistor includes a gate oxide layer 210, a first semiconductor doping layer 220 of a first conductivity type, and a second semiconductor doping layer 230 of a second conductivity type, when the insulated gate bipolar transistor operates in a high-voltage environment for a long time, after the bottom portion of the gate oxide layer 210 is broken down, the reverse PN junction formed by the first semiconductor doping layer 220 and the second semiconductor doping layer 230 can withstand the reverse voltage, thereby avoiding the occurrence of IGBT failure due to the short circuit between the first semiconductor doping layer 220 and the substrate 100. Accordingly, the stability and safety of the electronic device are improved.

In the description of the specification, the description with reference to terms “some embodiments”, “other embodiments”, “optional embodiments”, etc., means that the specific features, structures, materials or characteristics described in conjunction with the embodiments or examples are included in at least one embodiment or example of the present disclosure. In the specification, the illustrative descriptions of the above terms do not necessarily refer to the same embodiment or example.

The technical features in the above embodiments may be combined arbitrarily. In order to make the description concise, all possible combinations of the technical features in the above embodiments are not described. However, as long as there is no contradiction in the combinations of these technical features, these combinations should be considered to be within the scope of the present disclosure.

The above-described embodiments only express several implementation modes of the present disclosure, and the descriptions are relatively specific and detailed, but should not be constructed as limiting the scope of the present disclosure. It should be noted that, those of ordinary skill in the art can make several transformations and improvements without departing from the concept of the present disclosure, and these all fall within the protection scope of the present disclosure. Therefore, the protection scope of the present disclosure should be subject to the appended claims.

What is claimed is:

1. An insulated gate bipolar transistor, comprising:
a substrate of a first conductivity type; and
a plurality of gate structures arranged at intervals in the substrate, each gate structure comprising a gate oxide layer, a first semiconductor doping layer, and a second semiconductor doping layer, the first semiconductor doping layer being provided on the second semiconductor doping layer, the gate oxide layer being provided on sidewalls of the first semiconductor doping layer, and a bottom portion and sidewalls of the second semiconductor doping layer, the first semiconductor doping layer being of the first conductivity type, and the second semiconductor doping layer being of a second conductivity type opposite to the first conductivity type.

2. The insulated gate bipolar transistor according to claim 1, further comprising:
a body region of the second conductivity type located on the substrate of the first conductivity type and provided around the first semiconductor doping layer,
wherein a depth of the body region is less than a depth of the first semiconductor doping layer in a direction perpendicular to the substrate.

3. The insulated gate bipolar transistor according to claim 2, further comprising:
an active region of the first conductivity type located on the body region and provided around the gate structures.

4. The insulated gate bipolar transistor according to claim 1, wherein the first conductivity type is N-type and the second conductivity type is P-type.

5. The insulated gate bipolar transistor according to claim 1, further comprising:
a collector layer of the second conductivity type located on a surface of the substrate away from the gate structures.

6. The insulated gate bipolar transistor according to claim 3, wherein an upper surface of the active region is aligned with an upper surface of each gate structure.

7. A method for manufacturing an insulated gate bipolar transistor, comprising:
providing a substrate of a first conductivity type;
forming a plurality of trench structures arranged at intervals in the substrate;
forming a gate oxide layer at a bottom portion and sidewalls of each trench structure;
forming a second semiconductor doping layer on a side of the gate oxide layer away from the trench structure, a height of a top portion of the second semiconductor doping layer being less than a height of a top portion of the trench structure, the second semiconductor doping layer being of a second conductivity type opposite to the first conductivity type; and
forming a first semiconductor doping layer of the first conductivity type on the second semiconductor doping layer, wherein the gate oxide layer, the first semiconductor doping layer, and the second semiconductor doping layer form a gate structure.

8. The method according to claim 7, further comprising:
injecting ions of the second conductivity type into the substrate to form a body region, wherein a depth of the body region is less than a depth of the first semiconductor doping layer in a direction perpendicular to the substrate.

9. The method according to claim 8, further comprising:
injecting ions of the first conductivity type into the substrate above the body region to form an active region.

10. The method according to claim 7, further comprising:
forming a collector layer of the second conductivity type on a lower surface of the substrate.

11. The method according to claim 10, wherein forming the collector layer of the second conductivity type on a lower surface of the substrate comprises:
thinning a side of the substrate away from the gate structures, and injecting P-type ions to form the collector layer.

12. The method according to claim 10, wherein forming the collector layer of the second conductivity type on a lower surface of the substrate comprises:
depositing a metal layer on a side of the collector layer away from the substrate, wherein the collector layer is connected to an external circuit through the metal layer.

13. An electronic device, comprising the insulated gate bipolar transistor according to claim 1.
